(19) United States
(12) Patent Application Publication
(10) Pub. No.: US 2025/0224259 A1
(43) Pub. Date: Jul. 10, 2025

(54) METHOD FOR DETECTING A PRESENCE OF A HUMAN HAND IN A GRIPPING AREA OF A STEERING WHEEL

(71) Applicant: KOSTAL Automobil Elektrik GmbH & Co. KG, Luedenscheid (DE)

(72) Inventors: Christian BRÜGGEMANN, Waltrop (DE); Matthias SEIFERT, Bochum (DE); Tobias HEINLOTH, Dortmund (DE)

(73) Assignee: KOSTAL Automobil Elektrik GmbH & Co. KG, Luedenscheid (DE)

(21) Appl. No.: 19/096,396

(22) Filed: Mar. 31, 2025

Related U.S. Application Data
(63) Continuation of application No. PCT/EP2023/076487, filed on Sep. 26, 2023.

(30) Foreign Application Priority Data
Sep. 29, 2022 (DE) 102022003602.9

(51) Int. Cl. G01D 5/24

(52) U.S. Cl. CPC G01D 5/24

(57) ABSTRACT

A method for detecting a presence of a human hand in a gripping area of a steering wheel with the use of a capacitive sensor system is provided. The steering wheel includes a metal steering-wheel core connected to ground. The presence of the hand in a detection range of a sensor electrode arranged on the steering wheel and connected to sensor electronics brings about a change in a capacitive coupling of the sensor electrode at a reference potential. The steering-wheel core is connected to a second input of the sensor electronics. A voltage potential that is present between the connection of the steering-wheel core to the ground potential is continuously monitored by the sensor electronics. The monitored voltage potential may be used in correcting a determination of the capacitive coupling of the sensor electrode at the reference potential.

### CROSS-REFERENCE TO RELATED APPLICATIONS

This application is a continuation of International Application No. PCT/EP2023/076487, published in German, with an international filing date of Sep. 26, 2023, which claims priority to DE 10 2022 003 602.9, filed Sep. 29, 2022, the disclosures of which are hereby incorporated in their entirety by reference herein.

### TECHNICAL FIELD

The present invention relates to a method for detecting a presence of a human hand in a gripping area of a steering wheel by means of a capacitive sensor system, wherein the presence of the hand in a detection range of a sensor structure including a sensor electrode(s) connected to a first input/output of a sensor electronics system brings about a change in a capacitive coupling of the sensor electrode to a reference potential in comparison to a reference state without the presence of the hand in the gripping area, and a metal core of the steering wheel is connected to a ground potential.

### BACKGROUND

The sensor electrodes used here involve a one-or multi-layer structure of conductive sensor mats in the steering wheel rim. These capacitive sensor systems are referred to as hands-on detection (HOD) sensor systems. The presence of an operator's hand may be detected via a capacitive measurement. Use is made of the fact that a capacitive coupling exists between the hand and the sensor electrode, whose capacitance C_{Hand} is a function of the gripping state. The task of an associated sensor electronics system, or a measuring method used by such system, is to detect a change in the capacitance C_{Hand} caused by a change in the gripping state.

A difficulty is that the capacitance C_{Hand}, and particularly the changes thereof to be detected, are relatively much smaller in comparison to other internal capacitances of the steering wheel. For this reason, a so-called integration method is preferably used for this measurement. Pursuant to the integration method, in multiple consecutive cycles, small charge quantities are transferred from the sensor electrode, whose capacitance value is relatively small and variable, to an integration capacitor having a known, fixed capacitance value that is much greater. The voltage present at the integration capacitor after a predefined number of such integration cycles is measured using an A/D converter and processed to form a sensor amplitude. The sensor amplitude is a direct measure of the capacitance C_{Hand}. Other factors that may influence the measured capacitance must therefore be held constant to the greatest extent possible. For this purpose, in particular, the metal steering wheel core is connected to a fixed potential.

Sensor systems for steering wheels of motor vehicles for hand detection, using capacitive sensor structures, are known from the prior art. For example, DE 203 09 603 U1 discloses a steering wheel having sensor electrodes, arranged in sectors, which allow the approach and/or distancing of a human hand to be detected and associated with a certain area of the steering wheel.

WO 2016/087279 A1 discloses a steering wheel for a motor vehicle, having a capacitive sensor system whose sensor structure may also be operated, at least temporarily, as a heating structure. The steering wheel has a metal steering wheel core that may be operated as an active shielding element and acted on by a defined electric potential to reduce an interfering capacitive coupling of the sensor structure to the steering wheel core.

Due to the capacitance C_{Core} between the steering wheel core and a sensor electrode, which is much greater in comparison to the capacitance C_{Hand} between a human hand and the sensor electrode, a change in potential of the steering wheel core has an interfering effect on the HOD measurement. The connection of the steering wheel core to a fixed potential, which is provided to avoid this problem, takes place in a sensor electronics system. The impedance Z_{GND} of this potential connection, which generally occurs at a ground potential GND, typically has a capacitive portion of C_{GND}>100 nF.

The sensor electrodes and the steering wheel core are customarily connected via plug connectors to a wire harness that is led to the HOD electronics system and likewise connected thereto via plug connectors.

This situation as well as the relevant physical variables are schematically illustrated in FIG. 3, which illustrates a conventional HOD sensor system.

Faulty contacts or cable breaks in the potential connection of the steering wheel core may result in significant changes in the impedance Z_{GND}, and particularly in the capacitive portion C_{GND} thereof, thus leading to incorrect measurement results.

### SUMMARY

Embodiments of the present invention provide a method for detecting a presence of a human hand in a gripping area of a steering wheel. The method is for use with a capacitive sensor system in detecting the presence of the hand in the gripping area of the steering wheel. The capacitive sensor system includes a sensor electronics system and a sensor structure. The sensor structure includes at least one sensor electrode. The sensor electrode is connected to a first input/output of the sensor electronics system. The steering wheel includes a metal steering wheel core which is connected to a ground potential (GND). The presence of the hand in a detection range of the sensor electrode brings about a change in a capacitive coupling C_{Hand} of the sensor electrode to a reference potential in comparison to a reference state without the presence of the hand in the gripping area.

The method incudes determining the capacitive coupling C_{Hand} of the sensor electrode to the reference potential. The method further includes performing a diagnosis of the connection of the steering wheel core to the ground potential (GND) during runtime by connecting at least one contact point of the steering wheel core to a second input of the sensor electronics system, which carries out continuous monitoring of a voltage potential U_{Core} that is present. The method further includes using the monitored voltage potential U_{Core} to correct the determination of the capacitive coupling C_{Hand} of the sensor electrode to the reference potential.

A method for detecting a presence of a human hand in a gripping area of a steering wheel in accordance with embodiments of the present invention has the advantage, over the above-described background art, of avoiding errors pertaining to faulty contacts or cable breaks in the potential connection of the steering wheel core which may result in significant changes in the impedance Z_{GND}, and particularly in the capacitive portion C_{GND} thereof, thus otherwise leading to incorrect measurement results.

This is achieved according to the present invention in that a diagnosis of the connection of the steering wheel core to the ground potential is performed during runtime by connecting at least one contact point of the steering wheel core to a second input of the sensor electronics system, which carries out continuous monitoring of the voltage potential that is present.

A capacitive sensor system for detecting a presence of a human hand in a gripping area of the steering wheel is also provided. The steering wheel includes a metal steering wheel core connected to a ground potential. The capacitive sensor system includes a sensor electronics system and a sensor structure. The sensor structure includes a sensor electrode arranged on the steering wheel and connected to a first input/output of the sensor electronics system. The sensor electronics system is configured to determine a capacitive coupling C_{Hand} of the sensor electrode to a reference potential. A presence of a human hand in a detection range of the sensor electrode brings about a change in the capacitive coupling C_{Hand} of the sensor electrode to the reference potential in comparison to a reference state without the presence of the human hand in the detection range of the sensor electrode.

The sensor electronics system is further configured to perform a diagnostic measurement of the connection of the steering wheel core to the ground potential at a contact point of the steering wheel core connected to a second input of the sensor electronics system to continuously monitor a voltage potential U_{Core} that is present at the steering wheel core, and to correct the determined capacitive coupling C_{Hand} of the sensor electrode to the reference potential according to the monitored voltage potential U_{Core}.

Further advantageous embodiments of the method according to the present invention result from the following description of one possible design of the present invention.

### BRIEF DESCRIPTION OF THE DRAWINGS

The present invention is explained below with reference to the appended drawings. In the drawings:

FIG. 1 shows a schematic illustration of an embodiment of a hands-on detection (HOD) sensor system for carrying out a method according to the present invention, and relevant physical variables, in a first variant;

FIG. 2 shows a schematic illustration of an embodiment of the HOD sensor system for carrying out a method according to the present invention, and relevant physical variables, in a second variant; and

FIG. 3 shows a schematic illustration of a conventional HOD sensor system, and relevant physical variables.

### DETAILED DESCRIPTION

Detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

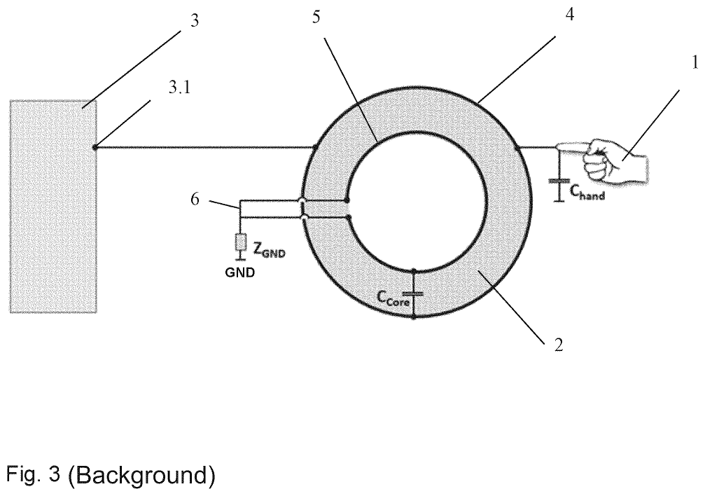

Referring initially to FIG. 3, a conventional hands-on detection (HOD) sensor system for detecting a presence of a human hand 1 in a gripping area of a steering wheel 2 is shown. The conventional HOD sensor system includes a sensor electronics system 3 and a sensor structure. The sensor structure includes at least one sensor electrode 4. Sensor electrode 4 is arranged on steering wheel 2 and is connected to an input/output 3.1 of sensor electronics system 3.

Steering wheel 2 includes a metal steering wheel core 5. A capacitance C_{Core} is between sensor electrode 4 and steering wheel core 5. Steering wheel core 5 is connected via one or more connection lines 6 to a fixed potential, which is generally a ground potential GND. This connection has an impedance Z_{GND} with a capacitance portion of typically C_{GND}>100 nF. Both single and multiple contacting of steering wheel core 5 are known; multiple contacting increases the robustness of the connection. However, a targeted diagnosis of this connection, particularly to detect an interruption of same, is not known thus far.

The presence of hand 1 in a detection range of sensor electrode 4 brings about a change in a capacitive coupling C_{Hand} of the sensor electrode to the hand. The change in the capacitive coupling C_{Hand} between sensor electrode 4 and hand 1 is detectable via input/output 3.1 of sensor electronics system 3. The capacitance C_{Core} between sensor electrode 4 and steering wheel core 5 is much greater in comparison than the capacitive coupling C_{Hand} between sensor electrode 4 and hand 1.

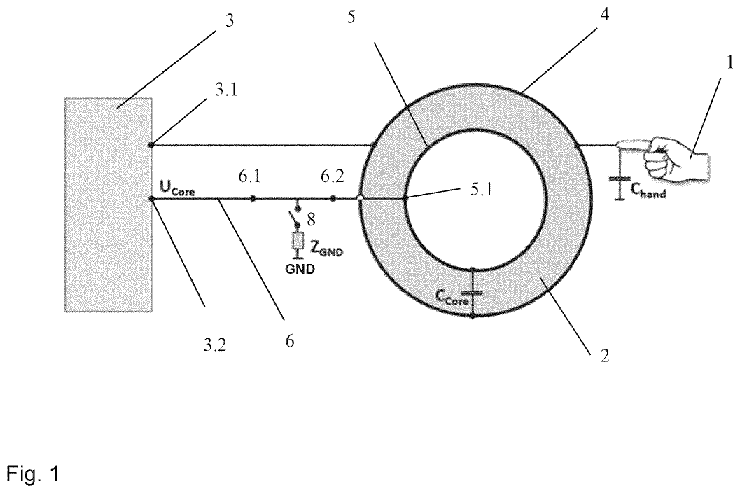

Referring now to FIG. 1, with continual reference to FIG. 3, a first variant of an embodiment of a HOD sensor system for carrying out a method according to the present invention is shown. The basic design of the HOD sensor system is identical to the above description of the conventional HOD sensor system shown in FIG. 3. In this regard, the HOD sensor system according to the present invention also includes a sensor electronics system 3 and a sensor structure, the sensor structure including at least one sensor electrode 4, and sensor electrode 4 is arranged on steering wheel 2 and is connected to a first input/output 3.1 of sensor electronics system 3. Likewise, the basic method steps carried out by the HOD sensor system according to the present invention for detecting the presence of a hand 1 in a gripping area of a steering wheel 2 are the same as set forth in the above description concerning the conventional HOD sensor system shown in FIG. 3. Lastly, steering wheel 2 includes a metal steering wheel core 5, per the above description concerning the conventional HOD sensor system shown in FIG. 3.

In the HOD sensor system shown in FIG. 1 there is additionally a connection of one of the lines 6, connecting steering wheel core 5 to the ground potential GND, to a further, second input 3.2 of sensor electronics system 3. By means of second input 3.2 of sensor electronics system 3, a capacitive voltage divider measurement is carried out in which the capacitive coupling between a contact point 5.1 of steering wheel core 5 and sensor electrode 4 across the capacitor C_{Core} is utilized. For this purpose, sensor electrode 4 is acted on by an activation signal, which the voltage U_{Core} present at steering wheel core 5 also follows due to the capacitive coupling C_{Core}. If the connection to the steering wheel core at one of the nodes 6.1 or 6.2 of connection line 6 is interrupted, the relationship of the voltage divider and thus the measured voltage U_{Core} change. A loss of the steering wheel connection to the ground potential GND may be detected via a value range diagnosis.

However, the voltage divider is dominated by Z_{GND} or C_{GND} (C_{GND}>100 nF, C_{Core}˜1 nF). To reliably detect an interruption at node 6, the connection to the fixed potential GND must be interrupted during the diagnostic measurement, which is achieved via an additional switch 8. Otherwise, the measured change in voltage would be too small, and therefore not robust against other influences on the measurement.

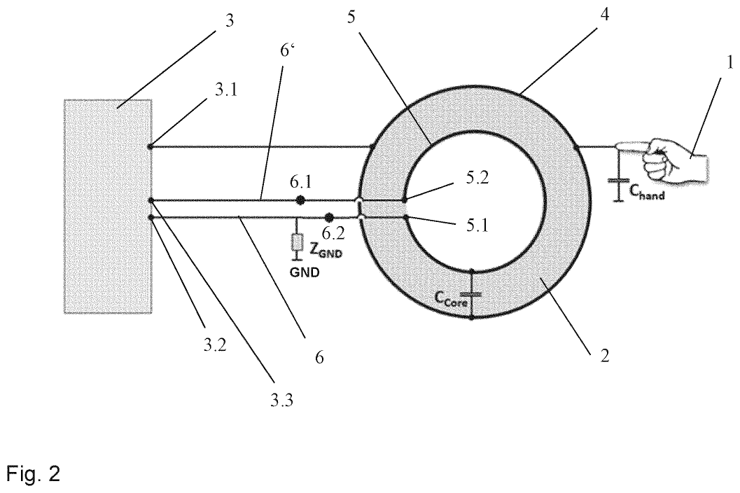

Referring now to FIG. 2, with continual reference to FIGS. 1 and 3, a second variant of an embodiment of a HOD sensor system for carrying out a method according to the present invention is shown. In contrast to the HOD sensor system shown in FIG. 1, in this case, in addition to the connection of a first contact point 5.1 of steering wheel core 5 to a second input 3.2 of sensor electronics system 3, there is a further connection of a second contact point 5.2 of steering wheel core 5 to a further, third input 3.3 of sensor electronics system 3. However, line 6′ of this further connection, in which node 6.1 is situated here, is not directly connected to the ground potential GND, in contrast to line 6 that is connected to second input 3.2 and in which node 6.2 is situated. An interruption in the connection at nodes 6.1 or 6.2 can be detected by means of a short circuit diagnosis.

While exemplary embodiments are described above, it is not intended that these embodiments describe all possible forms of the present invention. Rather, the words used in the specification are words of description rather than limitation, and it is understood that various changes may be made without departing from the spirit and scope of the present invention. Additionally, the features of various implementing embodiments may be combined to form further embodiments of the present invention.

What is claimed is:

1. A method for detecting a presence of a human hand in a gripping area of a steering wheel by means of a capacitive sensor system, the capacitive sensor system including a sensor electronics system and a sensor structure, the sensor structure including a sensor electrode arranged on the steering wheel and connected to a first input/output of the sensor electronics system, wherein the steering wheel includes a metal steering wheel core connected to a ground potential, the method comprising:
determining, by the sensor electronics system, a capacitive coupling C_{Hand} of the sensor electrode to a reference potential, wherein a presence of the human hand in a detection range of the sensor electrode brings about a change in the capacitive coupling C_{Hand} of the sensor electrode to the reference potential in comparison to a reference state without the presence of the human hand in the detection range of the sensor electrode;
performing, by the sensor electronics system, a diagnostic measurement of the connection of the steering wheel core to the ground potential at a contact point of the steering wheel core connected to a second input of the sensor electronics system to continuously monitor a voltage potential U_{Core} that is present at the steering wheel core; and
correcting the determined capacitive coupling C_{Hand} of the sensor electrode to the reference potential according to the monitored voltage potential U_{Core}.

2. The method according to claim 1, wherein:
performing the diagnostic measurement includes carrying out via the second input of the second electronics system a voltage divider measurement in which the capacitive coupling between the steering wheel core and the sensor electrode across a capacitive coupling C_{Core} is utilized.

3. The method according to claim 2, further comprising:
acting on the sensor electrode with an activation signal, which the voltage U_{Core} present at the steering wheel core follows due to the capacitive coupling C_{Core}.

4. The method according to claim 2, further comprising:
interrupting the connection of the steering wheel core to the ground potential during the diagnostic measurement via an additional switch.

5. The method according to claim 1, wherein a second contact point of the steering wheel core is connected to a third input of the sensor electronics system, the method further comprising:
detecting, by a short circuit diagnosis of the sensor electronics system, an interruption in the connection of the steering wheel core to the ground potential or in the connection of the steering wheel core to the third input of the sensor electronics system.

6. A capacitive sensor system for detecting a presence of a human hand in a gripping area of a steering wheel, wherein the steering wheel includes a metal steering wheel core connected to a ground potential, the capacitive sensor system comprising:
a sensor electronics system; and
a sensor structure including a sensor electrode arranged on the steering wheel and connected to a first input/output of the sensor electronics system;
the sensor electronics system is configured to determine a capacitive coupling C_{Hand} of the sensor electrode to a reference potential, wherein a presence of the human hand in a detection range of the sensor electrode brings about a change in the capacitive coupling C_{Hand} of the sensor electrode to the reference potential in comparison to a reference state without the presence of the human hand in the detection range of the sensor electrode;
the sensor electronics system is further configured to perform a diagnostic measurement of the connection of the steering wheel core to the ground potential at a contact point of the steering wheel core connected to a second input of the sensor electronics system to continuously monitor a voltage potential U_{Core} that is present at the steering wheel core, and to correct the determined capacitive coupling C_{Hand} of the sensor electrode to the reference potential according to the monitored voltage potential U_{Core}.
